(19) United States
(12) Patent Application Publication
(10) Pub. No.: US 2006/0228881 A1
(43) Pub. Date: Oct. 12, 2006

(54) Structure and method for minimizing substrate effect on nucleation during sputtering of thin film resistors

(75) Inventor: Eric W. Beach, Tucson, AZ (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/102,142

(22) Filed: Apr. 8, 2005

(51) Int. Cl. H01L 21/4763; H01L 21/31; H01L 21/469

(52) U.S. Cl. 438/626; 438/760

(57) ABSTRACT

A method of improving nucleation during depositing of a film (2) on a surface (18-3) of a wafer, including performing a planarizing operation on the surface (18-3), the planarizing operation resulting in generation of dangling chemical bonding sites on the surface, depositing a dielectric layer (18D) on the planarized surface (18-3) to cover the dangling chemical bonding sites to thereby produce a more uniform surface for nucleation of subsequently deposited resistive film material, and depositing a film (2) of resistive material on the dielectric layer (18D), whereby more uniform nucleation results in the film (2) being very uniform. The film of resistive material is deposited on the dielectric layer directly after the depositing of the dielectric layer, without any further treatment of the dielectric layer (18D).

### BACKGROUND OF THE INVENTION

The present invention relates generally to semiconductor structures and techniques for providing improved nucleation for deposition of one amorphous layer on another amorphous layer, and more particularly for deposition of thin film resistive materials on chemically/mechanically polished (CMP) or otherwise damaged surfaces of dielectric layers.

FIG. 1 shows a section view of a portion of a prior art integrated circuit including a thin film resistor structure in which a SiCr (sichrome) thin film resistor 2 is formed on an “interlevel dielectrics” region or layer 21 which may include several conventional dielectric layers (not shown). Layer 21 is formed on a “pre-metal dielectrics” or oxide layer 18 which is formed on a silicon layer 16. (The term “pre-metal dielectrics” is well-known in the integrated circuit industry, and refers to contiguous pre-metal dielectric layers having somewhat different doping, including for example, boron-phosphorus “TEOS” (tetrethylorthosilicate) layers.) A “head” 22A of SiCr film resistor 2 may be composed of TiW (titanium-tungsten) which extends through a sub-layer of a passivation layer 20 to make electrical contact with the left end of SiCr resistor 2. Head 22A also makes contact with a section 24A of a metallization layer 24A,B (typically formed of aluminum) formed on the upper surface of dielectric layer 21. In a similar manner, a separate portion 24B of metallization layer 24AB makes electrical contact to the right end of SiCr resistor 2. Interconnect conductors 24A and 24B of layer 24A,B extend along the surface of dielectric layer 21 and are connected to electrodes of various circuit elements (not shown) such as transistors, capacitors, and resistors, and may also be connected by appropriate conductive vias to another layer of metal conductors such as conductor 9.

FIG. 2 shows a portion of above-mentioned oxide layer 21, the upper surface 30 of which has been chemically/mechanically polished. A chemically/mechanically polished oxide surface always has an abraded and therefore damaged surface. (The damage also may be caused by a prior etching process such as a prior “etch back” process or a prior cleaning process such as a “sputter clean” process. Also, damage may be caused by a cleanup etching to remove slurry utilized in the chemical/mechanical polishing process.)

The damage 31 caused by conventional integrated circuit surface chemical/mechanical polishing may cause thin film resistors to have material stresses and/or discontinuities (especially in very thin layers such as SiCr layers which, for example, may be as thin as about only 30 Angstroms). Although the chemically/mechanically polished oxide surface 30 is very smooth, at an atomic level it is damaged such that there are chemical bonds that are not “passified” or “passivated”. Such damaged regions or sites of surface 30 in FIG. 2 are designated by reference numeral 31. For example, a molecule of a smooth oxide surface such as oxide surface 30 might add variance to the number of bonding sites due to the mechanical damage 31. The magnitude of the damage or surface roughness 31 of damaged surface 30 typically might have an RMS (root mean square) value of roughly 3 or 4 Angstroms.

As layers of an amorphous layer (such as SiCr) are being deposited on damaged regions 31 of surface 30, there is corresponding random un-evenness in the film being deposited. Therefore, if the SiCr is sputtered directly on damaged surface 30, the nucleation by means of which a thin layer of SiCr can be deposited onto a high-quality oxide film that has just been deposited will be much more nonhomogeneous and random than is the case if the SiCr is sputtered onto a perfect oxide surface. The somewhat random nucleation will result in random variations in the film thickness and consequently will result in random variations in resistivity at various sites within the thin film resistor over the damaged regions or sites 31. Therefore, the nonhomogeneous film of SiCr will have unpredictable, random resistivity variations therein and unpredictable, random variations in its sheet resistance.

Stated differently, a damaged or abraded dielectric surface prevents smooth, continuous nucleation of molecules being deposited along the damaged dielectric surface results in random thick and thin spots of reduced and increased resistivity, respectively, in the deposited film. This effect is enhanced as the deposited film becomes thinner.

The nucleation of material during PVD (physical vapor deposition) sputtering of thin film material is dependent on the surface condition of the substrate onto which the film material is being sputtered. Factors affecting the nucleation mechanism(s) include the cleanliness and physical condition of the substrate. Thin film resistors (typically about 30 Angstroms to 400 Angstroms thick) are very sensitive to the surface condition of the substrate on which they are deposited because the initial nucleation forms a significant percentage of the final film thickness.

There are several theories/mechanisms of nucleation occurring as material is deposited on a surface, and different boundary conditions may apply to each mechanism. One mechanism is referred to as “island growth”, wherein three-dimensional “islands” of deposited atoms (for CVD processes) or molecules (for PVD processes) are formed and wherein film atoms are more strongly bonded to each other than to substrate atoms. Another mechanism is referred to as “layer-by-layer growth”, wherein atoms or molecules of the film being deposited bond more strongly to the substrate atoms than to each other. A third mechanism includes initial layer-by-layer growth of the film followed by formation of three-dimensional islands of deposited atoms. The surface 30 can not be regarded simply as a featureless plane, and the initial growth of the film being deposited is impeded by damage 31 on the substrate. There is an important relationship of the amorphous film structure to the amorphous substrate structure that affects growth of the film being deposited, and that relationship is not sufficiently well-controlled if there is damage or residue on the substrate at the onset of deposition of the film. Defective nucleation sites on the substrate surface due to such damage are significant factors affecting the film deposition and the electrical properties of the resulting film.

In FIG. 2, the thin surface region 33 of oxide layer 21 contains the damage sites 31 that cause uneven resistivity within the deposited resistive film.

FIG. 3 illustrates four layers of SiCr molecules which have been deposited on an oxide layer 21A having a perfect surface. The perfect surface allows ideal nucleation of the SiCr molecules, resulting in the perfectly arranged layers of molecules 14, as illustrated. The SiCr molecules may have a diameter of approximately 5 or 6 Angstroms.

FIG. 4 is a magnified view which illustrates how the same SiCr molecules might be deposited on oxide layer 21 with the damaged surface 30 having damage features 31 as shown in FIG. 2. In FIG. 4, the SiCr molecules 14 are not arranged in perfect, repetitive layers, and the “stacking” of SiCr molecules results in amplified peaks which propagate upward as irregular nucleation continues to occur, first directly on damaged surface 30 and then on the already-deposited SiCr molecules. The deposited nonhomogeneous SiCr structure shown in FIG. 5 resulting from non-uniform nucleation during the SiCr deposition process results in random resistivity variations within the deposited layer, with the thinner sites having high resistivity and the thicker sites having low resistivity. This makes it difficult for the manufacturing process to meet a particular target sheet resistance specification for the resulting SiCr layers, and there will be a large variance in the statistical distribution of sheet resistances about the target sheet resistance. Furthermore, thin film resistors frequently are annealed in an oxidizing ambient or a nitrogen-rich ambient as part of the manufacturing process, and diffusion of the ambient species may be quite non-uniform as a result of “seams” or irregularities in the thin film layer caused by the non-uniform nucleation. That substantially increases the variability of the resistivity throughout the deposited thin film layer and therefore substantially increases the variance of the sheet resistance of the resistive film. Furthermore, the current density of current flowing through the variable resistivity regions in the thin film resistor may also vary, possibly causing high localized self-heating that leads to device failure.

In attempting to avoid the foregoing problems, various techniques have been used to remove the surface damage 31 on region 33 before depositing a resistive film on the damaged surface 30 of oxide layer 21. One such known technique has been to remove the surface-damaged region 33 by wet etching. FIG. 5 illustrates oxide layer 21 after the damaged region 33 has been etched away, producing a surface 30A on oxide layer 21. However, a problem with prior etching techniques for removing surface-damaged regions such as region 33 before depositing thin film resistive material such as SiCr, NiCr, or the like is that the quality of the etching process depends on the quality/properties of the material being etched as well as the etchant, and if the material being etched has a damaged surface, the damaged portion usually is preferentially etched at a much faster rate than the undamaged portion.

For example, a wet dip etch has been used to remove a surface-damaged region such as region 33 before depositing SiCr on the oxide layer 21. But this etching typically exposes various “facets” or “seams” of various wafer surface topology features to the etchant. Such facets or seams could be features in a layer such as above-mentioned pre-metal dielectric layer 18 or in an interlevel dielectric layer such as layer 21. For example, in a surface which has various features as in prior art FIG. 1 that have sharp corners between regions composed of dissimilar materials, there will be high stress forces in the corners. Every such facet or seam or corner includes associated stress points which are preferentially etched, typically at etch rates that are orders of magnitude greater than the bulk etch rate of the oxide or other dielectric. Similar preferentially etched stress points also occur at damaged locations of the oxide layer surface from which the surface-damaged region is to be removed by etching. Although the wet etching referred to above provides a cleaner surface of the oxide (or other dielectric) layer that is more favorable for nucleation of the resistive material to be deposited, the fast preferential etching of the various other stress point locations also causes various other highly undesirable problems. For example, FIG. 5 illustrates preferentially etched features 36 in a new surface 30A of oxide layer 21 after the surface-damaged region 33 has been removed by etching.

FIG. 6 illustrates a thin SiCr layer 2 which has been deposited on the oxide surface 30A including the “preferentially etched” or “stress-relief-etched” features 36. The upper surface of deposited SiCr layer 2 “follows”, and some cases even amplifies, the preferentially etched features 36 of oxide surface 30A, resulting in corresponding surface irregularities 36A on SiCr layer 2, as illustrated. The errors in resistivity of SiCr layer 2 resulting from the preferentially etched features 36 typically have a very large random variance, and for a thin SiCr layer (which may be as little as 30 Angstroms thick), the uneven nucleation described above due to the “stress relief etched” features 36 may even cause SiCr film 2 to be partly discontinuous. Any such discontinuity in SiCr film 2 would result in much higher sheet resistances than the expected target values thereof.

FIG. 7 shows a sectional view of a number of metal sections 9 formed on a plasma enhanced TEOS layer 18. A HDP oxide (high-density plasma oxide) layer 21 has been deposited over the metal layer 9 and plasma enhanced TEOS layer 18. As in prior art FIG. 1, portions of HDP oxide 21 on metal layer 9 are elevated relative to the portions on the surface of TEOS layer 18. Later, a plasma enhanced TEOS layer 20 is formed over HDP oxide 21, and the structure is subjected to chemical/mechanical polishing to provide a planarized surface.

Dashed line 26 surrounds a feature of FIG. 7 which is enlarged and illustrated as FIG. 8, wherein prior to depositing SiCr molecules 14, the chemically/mechanically polished surface is subjected to a wet cleaning etch which smooths the surface, but also results in preferential etching irregularities 29 along seams 28 between HDP oxide layer 21 and plasma enhanced TEOS layer 20. Then, as SiCr molecules 14 are deposited, the irregular nucleation in the vicinity of preferential etching irregularities 29 results in irregular nucleation, causing irregularities 39 which propagate upward in the SiCr layer as successive layers of atoms are deposited.

There is an unmet need for an inexpensive integrated circuit thin film resistor structure and method which avoids the effects of surface damage caused by prior techniques for removing or mitigating surface damage on a dielectric layer surface to be used as a substrate for depositing thin film resistive material.

There also is an unmet need for an improved, inexpensive integrated circuit thin film resistor structure and method for improving nucleation of resistive material being deposited on damaged dielectric surfaces.

### SUMMARY OF THE INVENTION

It is an object of the invention to provide a deposited film, such as a SiCr film, which is as continuous and clean as possible over a damaged surface.

It is another object of the invention to provide an inexpensive integrated circuit thin film resistor structure and method which avoids the effects of surface damage caused by prior techniques for removing or mitigating surface damage on dielectric layer surfaces on which thin film material is to be deposited.

It is another object of the invention to provide an improved, inexpensive integrated circuit thin film resistor structure and method for improving nucleation of material being deposited on abraded or otherwise damaged dielectric surfaces.

Briefly described, and in accordance with one embodiment, the present invention provides a method of improving nucleation during depositing of a film (2) on a surface (18-3) of a wafer, including performing a planarizing operation on the surface (18-3), the planarizing operation resulting in generation of dangling chemical bonding sites on the surface, depositing a dielectric layer (18D) on the planarized surface (18-3) to cover the dangling chemical bonding sites to thereby produce a more uniform surface for nucleation of subsequently deposited resistive film material, and depositing a film (2) of resistive material on the dielectric layer (18D), whereby more uniform nucleation results in the film (2) being very uniform. In the described embodiment, the film of resistive material is deposited on the dielectric layer directly after the depositing of the dielectric layer, without any further treatment of the dielectric layer (18D). In the described embodiments, the resistive material is one of the group consisting of NiCr, alloys of SiCr, alloys of NiCr, TaN, and alloys of TaN. In the described embodiments, the dielectric layer (18D) is a plasma enhanced TEOS layer having a thickness in the range of 100 to 500 Angstroms.

### BRIEF DESCRIPTION OF THE DRAWINGS

FIG. 1 is a section view diagram of a prior art thin film resistor structure.

FIG. 2 is a section view diagram useful in explaining surface damage due to chemical/mechanical polishing.

FIG. 3 is a section view diagram illustrating perfect nucleation of deposited SiCr molecules on a perfect oxide substrate.

FIG. 4 is a section view diagram illustrating non-uniform nucleation and deposition of SiCr molecules on a damaged oxide substrate.

FIG. 5 is a section view diagram useful in explaining surface damage due to preferential stress relief etching which occurs while removing chemical/mechanical polishing damage by an etching process.

FIG. 6 is a section view diagram illustrating how the surface damage in FIG. 5 affects a thin SiCr layer deposited thereon.

FIG. 7 is a section view diagram useful in explaining preferential etching along seams between topographical features of an integrated circuit.

FIG. 8 is an enlarged section view diagram of the region surrounded by dashed line 26 in FIG. 7 after deposition of SiCr molecules.

FIG. 9 is a section view of an integrated circuit structure including a thin film resistor fabricated in accordance with the present invention.

FIGS. 10 and 11 are section view diagram useful in explaining the present invention.

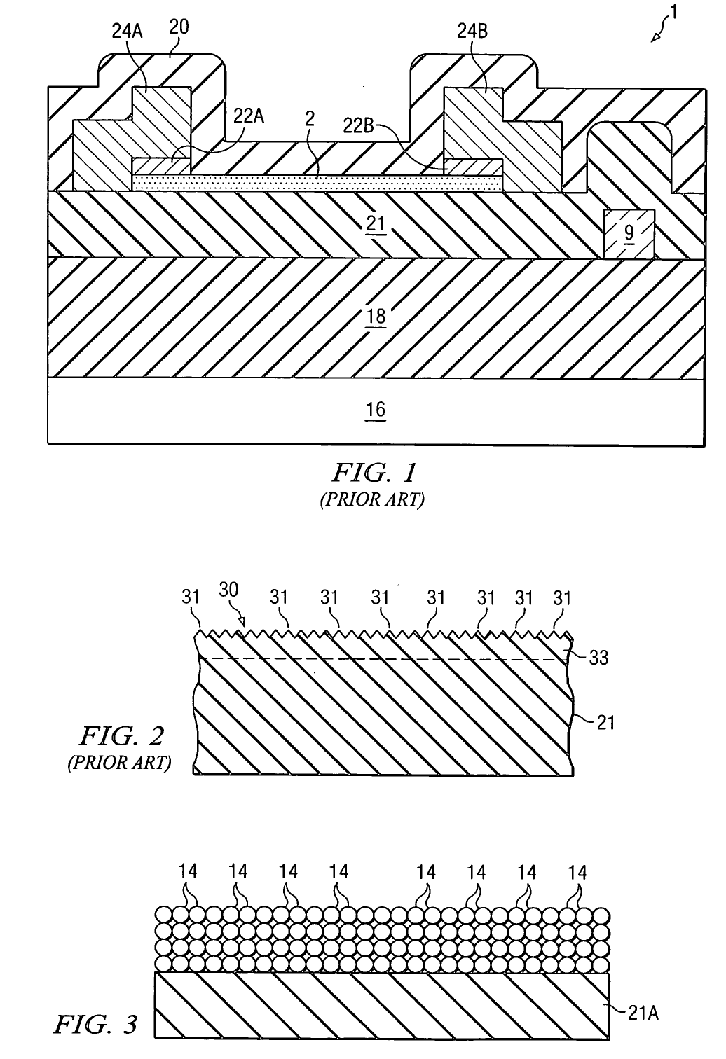

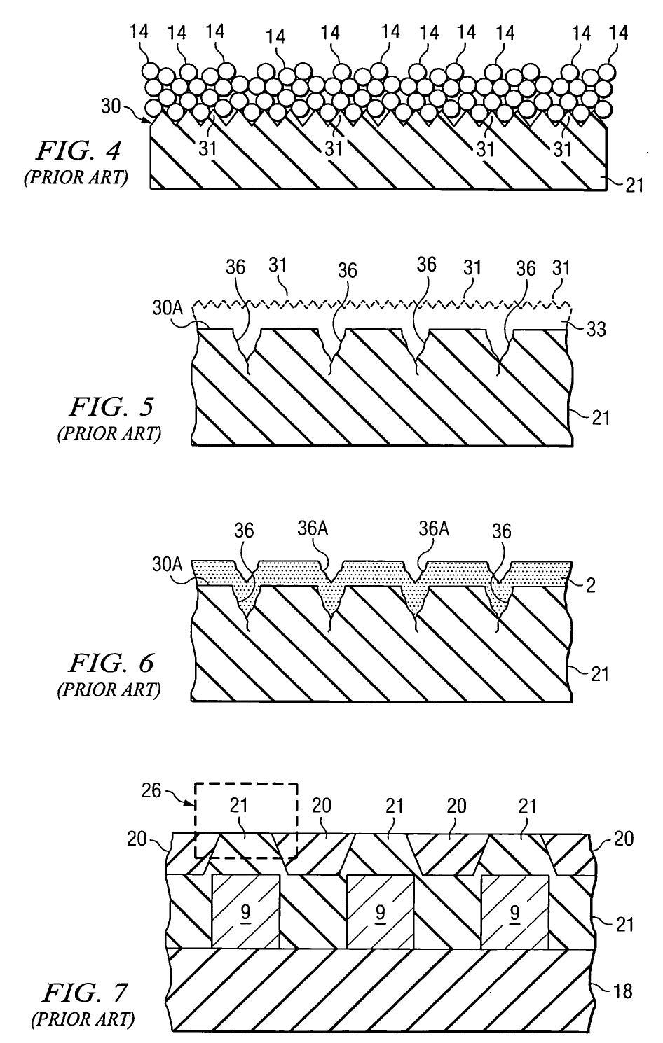

### DETAILED DESCRIPTION OF THE PREFERRED EMBODIMENTS

Referring to FIG. 9, pre-metal dielectrics region 18 is formed on silicon substrate 16, which could be an epitaxial silicon layer formed directly on a semiconductor wafer. Region 18 includes a dielectric layer 18A formed on the upper surface of silicon layer 16. An arrangement of optional parallel polycrystalline silicon strips 9B can be formed on the upper surface 18-1 of dielectric layer 18A to form a first dummy fill layer, and another dielectric layer 18B is formed on surface 18-1 of dielectric layer 18A and the first dummy fill layer 9B. A layer of spaced metallization strips 9A and/or other metallization interconnect pattern (not shown) forms an optional second dummy fill layer on a chemically/mechanically polished surface 18-2 of dielectric layer 18B. A dielectric layer 18C is formed on surface 18-2 of dielectric layer 18B and the metallization pattern 9A. The upper surface 18-3 of dielectric layer 18C is planarized by a conventional chemical/mechanical polishing process, which causes the above described kind of damage on surface 18-3 of dielectric layer 18C.

In accordance with the present invention, a thin layer 18D, which can be a TEOS layer, is formed on chemically/mechanically polished (and therefore damaged) surface 18-3 to provide an undamaged surface 18-4 thereof on which uniform nucleation can occur during a subsequent film deposition process. (Layer 18D also could be a silane based oxide, silicon nitride, or silicon carbide layer or any of a number of common CVD based dielectric layers.) TEOS layer 18D is a “clean” layer in the sense that it has not been altered or treated in any significant way after being deposited. For example, no photo resist has been deposited on or removed from surface 18-4, nor has it been subjected to any kind of etching, cleaning, chemical or mechanical polishing, or slurry-cleaning etc process or the like.

An interlevel dielectrics region 21 shown in FIG. 9 includes a dielectric layer 21A formed on SiCr resistor 2 and on the exposed area of planar surface 18-4 of TEOS layer 18D. A conventional thin film resistor head 22A composed of TiN (titanium nitride) extends through an opening 27 in dielectric layer 21A to make reliable electrical contact with the left end of SiCr resistor 2. Another dielectric layer 21B is formed on dielectric layer 21A. Resistor head 22A also makes electrical contact with the bottom of a tungsten via or plug 23A which extends to the top of interlevel dielectric layer 21 through an opening 28 therein. A portion 24A of a metallization layer 24A,B formed on the upper surface of interlevel dielectric layer 21 electrically contacts the top of tungsten plug 23A. (By way of definition, the term “layer” as used herein is intended to include a layer having multiple sections which may be but are not necessarily connected and/or contiguous to each other. Thus, metallization layer 24A,B includes sections 24A and 24B which are not connected to each other and are not contiguous.)

In a similar manner, a separate portion 24B of metallization layer 24AB makes electrical contact through tungsten plug 23B and TiN thin film head 22B to the right end of SiCr resistor 2. A TEOS passivation layer 20 is formed on metallization layer 24A,B and dielectric layer 21B.

In accordance with the present invention, the placement of a thin, “clean” dielectric film over a surface-damaged dielectric layer has been found to improve nucleation and also the repeatability of nucleation during sputtering of an amorphous thin film, such as SiCr, NiCr, TaN, or alloys thereof, on the thin, clean dielectric film.

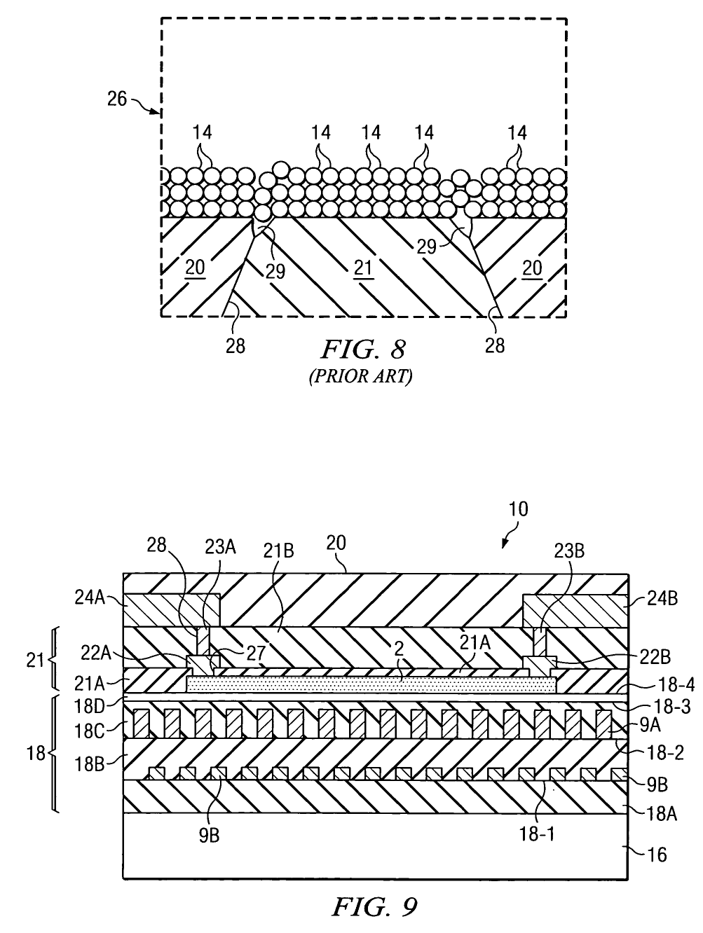

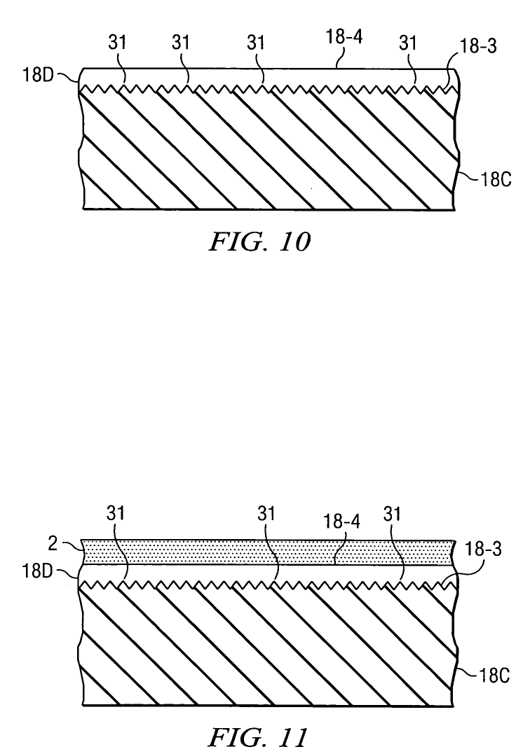

FIG. 10 shows damaged dielectric layer 18C, including damaged surface 18-3 and individual damaged regions 31 thereof, and also shows a plasma enhanced TEOS layer 18D and its undamaged surface 18-4 at this stage of the process. The damage features 31 on chemically/mechanically polished surface 18-3 typically are less than about 10 Angstroms in magnitude. TEOS layer 18D preferably has a thickness in the range of 100 Angstroms to 500 Angstroms. Therefore, TEOS layer 18D has a very effective smoothing or averaging effect on surface damage 31 and preferentially etched features such as 29 in prior art FIG. 8. Plasma enhanced TEOS deposition is presently preferred for achieving the desired uniform thickness of TEOS layer 18D. This is because when oxide is deposited on topographical features of an integrated circuit, the deposition resulting oxide layer typically is thicker on the horizontal surfaces than on the vertical side wall surfaces of the topographical features. However, it is preferable that such an oxide have nearly uniform thickness on both horizontal and vertical surfaces of topographical features on which it is deposited, so that stress forces are smoothed out rather than propagated upward during the sputtering. Plasma enhanced TEOS processing achieves this objective at suitable processing temperatures much better than various known silane based oxide deposition processes performed in low temperature LPCVD (low-pressure chemical vapor deposition) reactors.

Referring to FIG. 11, a SiCr resistive film 2 is deposited on undamaged surface 18-4 of TEOS layer 18D. In a preferred embodiment, SiCr resistive film 2 is approximately 32 Angstroms thick, although its thickness may well be in the range from approximately 20 to 200 Angstroms. (Alternatively, resistive film 2 can be composed of other suitable deposited thin film resistive material such as NiCr, alloys of SiCr, alloys of NiCr, TaN (tantalum nitride), or alloys of TaN which could be deposited on undamaged surface 18-4.) FIG. 11 shows the structure of FIG. 10 after SiCr layer 2 has been deposited on undamaged surface 18-4 of TEOS layer 18D. The clean, undamaged surface 18-4 of plasma enhanced TEOS layer 18D is believed to result in substantially improved uniformity and repeatability of nucleation during the sputtering of a resistive thin-film layer on surface 18-4 and provides much more uniform resistivity and sheet resistance of the sputtered resistive film 2. Even though slightly irregular nucleation of SiCr molecules might occur during the deposition of SiCr molecules on plasma enhanced TEOS layer 18D over any preferentially etched features that are present in oxide layer 18C (such as preferentially etched features 29 in FIG. 8), the molecules of the deposited SiCr layer 2 in FIG. 11 are believed to be very uniformly aligned, similarly to molecules 14 deposited on perfect oxide 21A as shown in FIG. 3.

An advantage of the invention is that it provides a deposited resistive film (even an extremely thin deposited film such as 30 Angstrom thick SiCr films that can be used) which is as continuous and clean as possible, and thereby avoids the damaging effects of prior art etching techniques for removing surface damage from the surface on which the resistive film is to be deposited. Another advantage of the invention is that it substantially mitigates issues with respect to highly accelerated preferential etching at stress points in seams in the dielectric surface and in other topological features of the integrated circuit being fabricated. This results in a great improvement in the accuracy of the resistivity and sheet resistance of a thin film and in the ability of the thin film manufacturing process to achieve target values of sheet resistance. Other advantages of the invention include the fact that the dependence of the resistivity of the deposited thin film is not dependent on the etch rate and/or etch uniformity in removing of damaged surface material across the wafer.

While the invention has been described with reference to several particular embodiments thereof, those skilled in the art will be able to make various modifications to the described embodiments of the invention without departing from its true spirit and scope. It is intended that all elements or steps which are insubstantially different from those recited in the claims but perform substantially the same functions, respectively, in substantially the same way to achieve the same result as what is claimed are within the scope of the invention. For example, even though only integrated circuit implementations of the invention have been described in detail, those skilled in the art could readily provide a discrete thin film resistor structure in accordance with the invention.

What is claimed is:

1. A method of improving nucleation during depositing of a film on a surface of a wafer, comprising:
(a) performing a planarizing operation on the surface, the planarizing operation resulting in generation of surface damage causing dangling chemical bonding sites on the surface;
(b) depositing a dielectric layer on the planarized surface to cover the dangling chemical bonding sites to thereby produce a more uniform surface for nucleation of subsequently deposited resistive film material; and
(c) depositing a film of resistive material on the dielectric layer, whereby more uniform nucleation of molecules of the resistive material results in the film being very uniform.

2. The method of claim 1 wherein step (c) is performed directly after step (b) without any further treatment of the dielectric layer.

3. The method of claim 1 wherein the magnitude of surface damage is generally less than approximately 10 Angstroms.

4. The method of claim 1 wherein the resistive material is SiCr material.

5. The method of claim 1 wherein the resistive material is one of the group consisting of NiCr, alloys of SiCr, alloys of NiCr, TaN, and alloys of TaN.

6. The method of claim 4 wherein the thickness of the SiCr material is in the range from approximately 20 to 200 Angstroms.

7. The method of claim 1 wherein the dielectric layer is a plasma enhanced TEOS layer.

8. The method of claim 7 wherein the thickness of the dielectric layer is in the range of approximately 100 to 500 Angstroms.

9. A thin film resistor structure comprising:
(a) a dielectric layer having a damaged planar surface;
(b) an oxide layer disposed on the dielectric layer, the oxide layer being sufficiently thick to have a damage-free planar surface; and
(c) a thin film resistive layer disposed on the damage-free planar surface.

10. The thin film resistor structure of claim 9 wherein the oxide layer is a plasma enhanced TEOS layer.

11. The thin film resistor structure of claim 10 wherein the thin film resistive layer is composed of material from the group including SiCr, NiCr, alloys of SiCr, alloys of NiCr, TaN, and alloys of TaN.

12. The thin film resistor structure of claim 9 wherein the thickness of the oxide layer is in the range of approximately 100 to 500 Angstroms.

13. The thin film resistor structure of claim 9 wherein the thin film resistive layer is composed of SiCr and has a thickness in the range of approximately 20 to 200 Angstroms.

14. The thin film resistor structure of claim 9 including an inter-level dielectric layer on the thin film resistive layer and the oxide layer, and a metal layer on the inter-level dielectric layer, a portion of the metal layer extending to a head portion of the thin film resistive layer through a contact opening in the first inter-level dielectric layer.

15. The thin film resistor structure of claim 9 wherein the magnitude of surface damage of the damaged planar surface is less than approximately 10 Angstroms.

16. An integrated circuit thin film resistor structure comprising:
(a) a dielectric layer having a damaged planar surface, the dielectric layer being an upper layer of a pre-metal dielectric structure of an integrated circuit;
(b) a plasma enhanced TEOS layer disposed on the dielectric layer, the TEOS layer being sufficiently thick to have a damage-free planar surface; and
(c) a thin film resistive layer disposed on the damage-free planar surface.

17. The integrated circuit thin film resistor structure of claim 16 wherein the thin film resistive layer is composed of material from the group including SiCr, NiCr, alloys of SiCr, alloys of NiCr, TaN, and alloys of TaN.

18. The integrated circuit thin film resistor structure of claim 16 wherein the thickness of the TEOS layer is in the range of approximately 100 to 500 Angstroms.

19. The integrated circuit thin film resistor structure of claim 16 wherein the magnitude of surface damage of the damaged planar surface is less than approximately 10 Angstroms.

20. The integrated circuit thin film resistor structure of claim 16 9 including an inter-level dielectric layer on the thin film resistive layer and the oxide layer, and a metal layer on the inter-level dielectric layer, a portion of the metal layer extending to a head portion of the thin film resistive layer through a contact opening in the first inter-level dielectric layer.
